(19) United States
(12) Patent Application Publication
(10) Pub. No.: US 2013/0077795 A1
(43) Pub. Date: Mar. 28, 2013

(54) Over-Excursion Protection for Loudspeakers

(71) Applicants: Lars Risbo, Hvalsoe (DK); Milind Anil Borkar, Dallas, TX (US); Theis Buchwald Christiansen, Kobenhavn N (DK)

(72) Inventors: Lars Risbo, Hvalsoe (DK); Milind Anil Borkar, Dallas, TX (US); Theis Buchwald Christiansen, Kobenhavn N (DK)

(73) Assignee: TEXAS INSTRUMENTS INCORPORATED, Dallas, TX (US)

(21) Appl. No.: 13/247,554

(22) Filed: Sep. 28, 2011

(51) Int. Cl. H03G 11/00

(52) U.S. Cl. 381/55

(57) ABSTRACT

In an embodiment of the invention, over-excursion of a diaphragm in an electro dynamic transducer is reduced by attenuating low frequency content in an audio signal when the power of an audio signal exceeds a predetermined power limit. The audio signal is used to drive the input of an amplifier and the output of the amplifier drives the electro dynamic transducer. When the audio signal does not exceed a predetermined power limit, the low frequency content in the input audio signal is amplified.

### CROSS-REFERENCED TO RELATED APPLICATIONS

This application is related to Ser. No. ______ (TI-70801) entitled “Thermal Protection for Loudspeakers”, and to Ser. No. ______ (TI-71350) entitled “Thermal Control of Voice Coils in Loudspeakers”, filed on even date herewith and are hereby incorporated by reference for all that is disclosed therein.

### BACKGROUND

Loudspeakers used in compact and portable devices require significant design compromises that may lead to suboptimal sound quality and loudness. A loudspeaker used in a compact device (e.g. a cellular phone, an electronic tablet, a laptop computer, a PDA (personal digital assistant), a media player etc.) is usually small. As a result, the sensitivity of the loudspeaker can be low and the diaphragm on the loudspeaker can have a limited range of motion. Often loudspeakers are driven beyond their range of motion in order to obtain the loudness needed to hear the audio signal coming from it.

Driving a loudspeaker beyond its range of motion can cause the diaphragm in a loudspeaker to move beyond its linear region (i.e. over-excursion). When a loudspeaker moves beyond its linear region, the sound produced by the loudspeaker can be distorted. Distortion can make the sound coming from the loudspeaker irritating. In some cases the distortion can be so bad as to make a conversation unintelligible.

In addition to causing distortion, driving a loudspeaker beyond its range of motion can cause mechanical stress to the components of the loudspeaker. For example, over-excursion can cause the surround material that supports the diaphragm of a loudspeaker to tear. When the surround material of a loudspeaker tears it can cause more distortion. In some cases, a tearing of the surround material can make the loudspeaker inoperable.

Loudspeakers used in compact devices are relatively cheap. However, damage to a loudspeaker in a compact device may cause a return of the entire device. In order to reduce the damage done to loudspeakers and improve the loudness and quality of the loudspeakers, power applied to loudspeakers needs to be controlled to reduce over-excursion of the diaphragm in loudspeakers.

### BRIEF DESCRIPTION OF THE DRAWINGS

FIG. 1 is a cross-sectional view of an electro dynamic transducer (Prior Art).

FIG. 2 is a block diagram of a first embodiment of an over-excursion system used to protect an electro dynamic transducer.

FIG. 3 is a frequency plot of a 4^{th} order Linkwitz-Riley low-pass filter (Prior Art).

FIG. 4 is a frequency plot of a 4^{th} order Linkwitz-Riley high-pass filter (Prior Art).

FIG. 5 is a frequency plot of the sum of the output of the dynamic power limiter and the output of the high-pass filter as function of the gain G of an amplifier.

FIG. 6 is a block diagram of a second embodiment of an over-excursion system used to protect an electro dynamic transducer.

FIG. 7 is a plot of the excursion of a diaphragm in an electro dynamic transducer versus measured inductance of a voice coil in the electro dynamic transducer.

FIG. 8 is a flow diagram of an embodiment of a method of protecting a diaphragm in an electro dynamic transducer from over-excursion.

FIG. 9 is a block diagram of a third embodiment of an over-excursion system used to protect an electro dynamic transducer.

### DETAILED DESCRIPTION

The drawings and description, in general, disclose a method for reducing over-excursion of a diaphragm in an electro dynamic transducer. As part of the method, an estimate of the excursion of the diaphragm in the electro dynamic transducer is obtained while the power of an audio signal is measured. After the estimate of the excursion is obtained and the power of the audio signal is measured, the low frequency content of the audio signal is reduced when a power limit is exceeded and/or an excursion limit is exceeded.

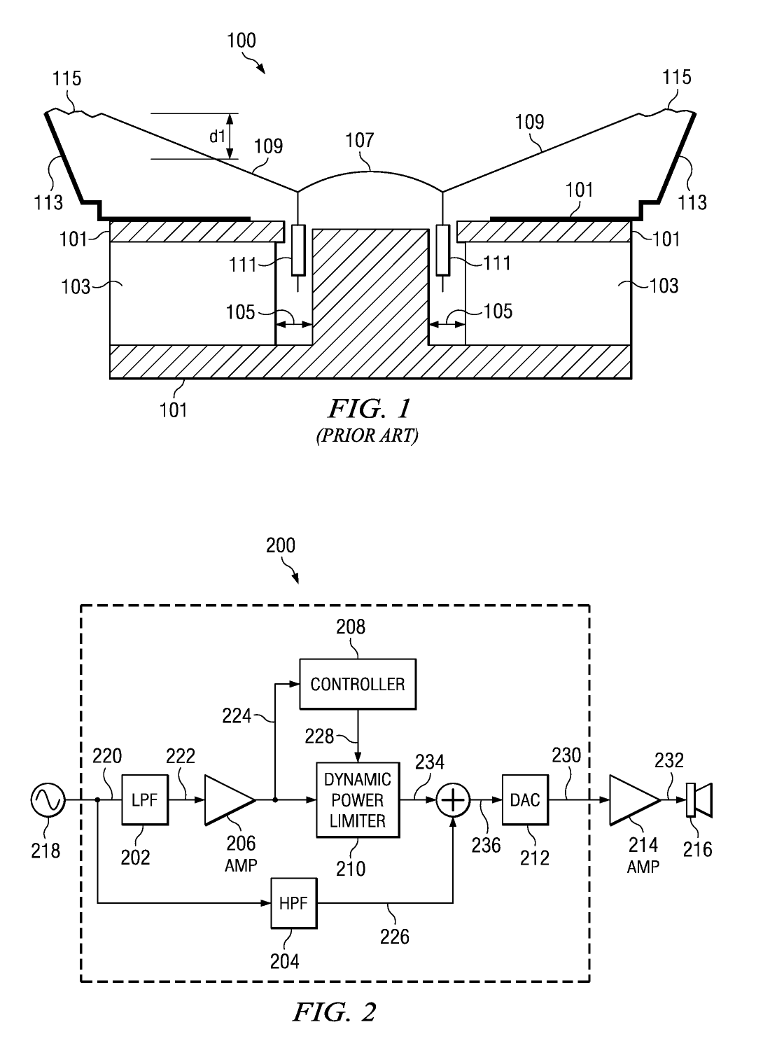

FIG. 1 is a cross-sectional view of an electro dynamic transducer (loudspeaker) 100 (Prior Art). The electro dynamic transducer 100 may be used in a cellular phone, an electronic tablet, a laptop computer, a desktop computer, a television, a monitor, a portable radio, a portable musical playback system, a PDA and a media player. In this example of an electro dynamic transducer 100, the voice coil 111 is located in the magnetic field of the magnetic gap 105. The voice coil 111 is physically attached to the dome 107 of the electro dynamic transducer 100. A diaphragm 109 is attached to the dome 107 and to a surround 115 of the electro dynamic transducer 100. The surround 115 is also attached to the frame 113. The magnet 103 and the magnetic circuit 101 provide a magnetic field for the voice coil 111.

The voice coil 111 provides the motive to the diaphragm 109 by the reaction of the magnetic field provided by the magnet 103 and the magnetic circuit 101 to the current flowing through the voice coil 111. By driving a current through the voice coil 111, a magnetic field is produced. This magnetic field causes the voice coil 111 to react to the magnetic field from the permanent magnet 103 fixed to the loudspeaker's frame 113 thereby moving the diaphragm 109 of the electro dynamic transducer 100. By applying an audio signal to the voice coil 111, the diaphragm 109 will reproduce the sound pressure waves corresponding to the original audio signal.

The range of motion d1 that the diaphragm 109 may move and remain reasonably linear is shown in FIG. 1. When the diaphragm moves beyond the range of motion d1, the electro dynamic transducer 100 will cause distortion because the movement of the diaphragm 109 is no longer linear. Keeping the diaphragm 109 within this range of motion d1 may be controlled by monitoring the movement of the diaphragm 109 and dynamically adjusting the current conducted in the voice coil 111 based on the measured movement of the diaphragm 109.

FIG. 2 is a block diagram of an embodiment of an over-excursion protection system 200 used to protect an electro dynamic transducer 212 from over-excursion. The protection system 200 comprises a low-pass filter 202, a high-pass filter 204, an amplifier 206 with a gain G, a controller 208, a dynamic power limiter 210 and a DAC (digital to analog converter) 212. The over-excursion protection system 200 along with the amplifier 214 may be integrated on a single integrated circuit. In this example, the low-pass filter 202, the high-pass filter 204, the amplifier 206, the controller 208 and the dynamic power limiter 210 are digital circuits. As consequence, the input audio signal 220 is a digital signal.

An input audio signal 220 is applied to the input of the low-pass filter 202 and to the input of the high-pass filter 204. In order to reproduce audio low frequency signals a diaphragm 109 in an electro dynamic transducer 212 must move more than it would when reproducing higher frequency audio signals. To better control movement of the diaphragm 109, low frequency signals are removed by the high-pass filter 204. In this embodiment of the invention, the high-pass filter 204 is a Linkwitz-Riley 4^{th} order cross-over with a cross-over frequency of 1 KHz. Different types and different order high-pass cross-overs may be used. The frequency response of the high-pass filter is shown in FIG. 4. In this embodiment of the invention, the low-pass filter 202 is a Linkwitz-Riley 4^{th} order cross-over with a cross-over frequency of 1 KHz. Different types and different order low-pass cross-overs may be used.

In addition to the filters described above, shelving filters may also be used. The response curve of shelving filters most closely resembles the high-pass and low-pass filters described above with a minor difference. The frequency curve of these filters level out at a specified frequency called the stop frequency. In addition, there is a second defining frequency called the turnover frequency which is the frequency at which the response is 3 dB above or below 0 dB. The transition ratio Rₜ is analogous to the order of the filter. Rₜ is equal to the stop frequency Fₛₜₒₚ divided by the turnover frequency Fₜᵤᵣₙₒᵥₑᵣ. The closer the transition ratio Rₜ is to 1, the greater the slope of the transition in gain from the unaffected to the affected frequency ranges.

Shelving filters are available as high- and low-frequency shelving units, boosting high and low frequencies respectively. In addition, they typically have a symmetrical response. If the transition ratio Rₜ is less than 1, then the filter is a low shelving filter. If the transition ratio Rₜ is greater than 1, then the filter is a high shelving filter.

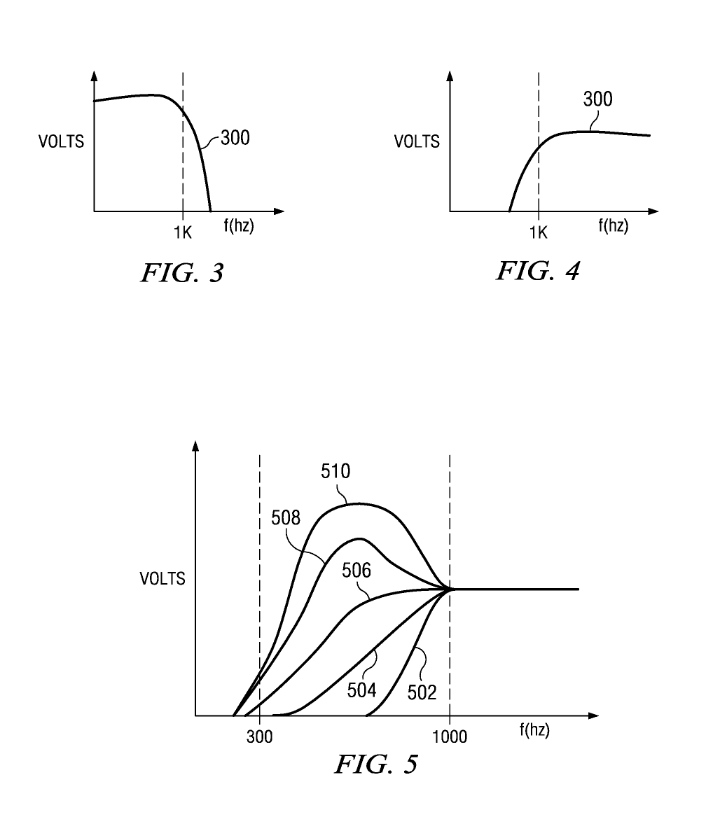

The frequency response of the low-pass filter 202 is shown in FIG. 3. The low-pass filter 202 allows low frequency audio signals to pass to the amplifier 206. In this example the amplifier 206 has a voltage gain of G. As a result, the voltage of the signal passed to the input 222 of the amplifier 206 is amplified by G. The output signal 224 of the amplifier 206 is passed to a controller 208 and a dynamic power limiter 210.

In this embodiment of the invention shown in FIG. 2, the controller 208 controls (through signal 228) the amount of low frequency energy allowed to pass through the dynamic power limiter 210 based on predetermined power limits. The dynamic power limiter 210 based on signal 228 multiplies the output 224 of the amplifier 206 by X where X ranges from 0 to 1. For example, when the power of the output signal 224 is very high, the dynamic power limiter 210 multiplies the output signal 224 by 0 resulting in practically no low frequency energy leaving the dynamic power limiter 210. In an other example, when the power of the output signal is lower than the previous example, the controller 208 instructs the dynamic power limiter to multiply the output signal 224 by 0.5 resulting in an output signal 234 with a voltage reduced by half.

The sum 236 of the output 234 of the dynamic power limiter 210 and the output 226 of the high-pass filter 204 is then applied to the DAC 212. The DAC 212 converts the sum 236 to an analog signal 230. The analog signal 230 then drives the power amplifier 214. The power amplifier 214 then drives the electro dynamic transducer 216.

Because the analog signal 230 has controlled low frequency content, the output 232 of the power amplifier 210 does not drive the diaphragm 109 of the electro dynamic transducer 216 beyond the excursion limits of the diaphragm 109.

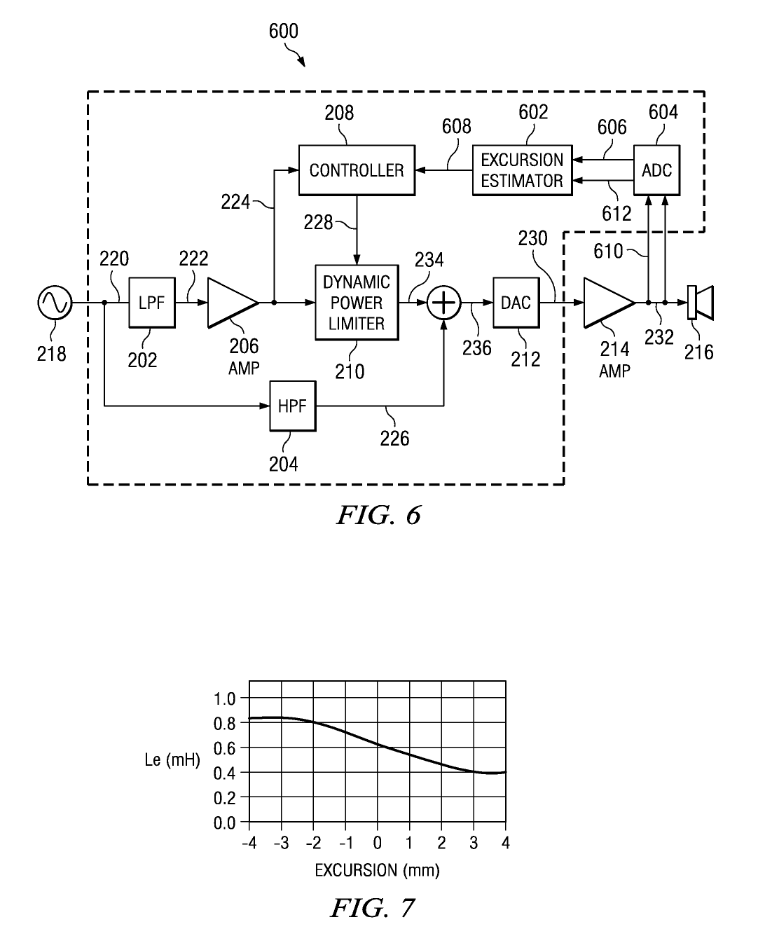

FIG. 6 is a block diagram of a second embodiment of an over-excursion system used to protect an electro dynamic transducer 216. This embodiment is similar to the embodiment shown in FIG. 2 in that it controls the low frequency content by monitoring the low frequency content of the input audio signal. The second embodiment shown in FIG. 6 also includes an instantaneous estimate of the excursion d1 of the diaphragm 109 of an electro magnetic transducer 216. When the instantaneous estimate of the excursion d1 of the diaphragm 109 exceeds predetermined limits, the controller 208 instructs the dynamic power limiter 210 to reduce the amount of low frequency energy in the input signal. Methods of determining the instantaneous excursion of the diaphragm will be explained in more detail later in the specification.

The over-excursion protection system 600 shown in FIG. 6 comprises a low-pass filter 202, a high-pass filter 204, an amplifier 206 with a gain G, a controller 208, a dynamic power limiter 210, a DAC (digital to analog converter) 212, an ADC (analog to digital converter) 604, and an excursion estimator 602. The over-excursion protection system 600 along with the amplifier 214 may be integrated on a single integrated circuit. In this example, the low-pass filter 202, the high pass filter 204, the amplifier 206, the excursion estimator 602, the controller 208 and the dynamic power limiter 210 are digital circuits. As consequence, the input audio signal 220 is a digital signal.

In a first example of a method used to estimate the excursion of a diaphragm 109 in electro dynamic transducer 216, a high frequency pilot tone (i.e. above 20 KHz and inaudible) is applied to the voice coil of the electro dynamic transducer 216. The reactance (imaginary part of the impedance of the voice coil) of the high frequency pilot tone can be measured. The reactance of the high frequency pilot tone can be used to determine the inductance of the voice coil. For a specific electro dynamic transducer 216, the excursion of a diaphragm 109 can be estimated given the inductance of the voice coil.

For example, the excursion of diaphragm 109 can be estimated given the inductance Lₑ as shown in FIG. 7. The estimate of the excursion of the diaphragm 109 based on the inductance Lₑ as shown in FIG. 7 can be used to make a lookup table or an equation in the excursion estimator 602. The inductance may be estimated be estimated several ways. In a first example, the inductance may be estimated by measuring the current 610 in the voice coil 111 and voltage 232 on the voice coil 111. As a result when a digital value 606 for voltage across the voice coil 111 and a digital value 612 for the current in the voice coil 111 are presented on inputs of the excursion estimator 602, a digital estimate 608 of the excursion of the diaphragm 109 can be presented to controller 208.

The controller 208 based on the digital excursion estimate 608 can determine whether the low frequency content of the input signal should be attenuated or not. For example, when the instantaneous excursion estimate 608 exceeds a predetermined excursion limit for an electro dynamic transducer 216, the controller will send a digital signal 228 to the dynamic power limiter 210. The dynamic power limiter 210 will then multiply the low frequency content 224 by X where X ranges from 0 to 1. The reduced low frequency content signal 234 is then added to the high frequency content signal 226 supplied by the high-pass filter 204.

The sum 236 of the reduced low frequency content signal 234 and the high frequency content signal 226 is then applied to the DAC 212. The DAC 212 converts the digital sum 236 to an analog signal 230. The analog signal 230 then drives the power amplifier 214. Because the analog signal 230 has some low frequency energy removed, the output 232 of the power amplifier 214 does not cause over-excursion of the diaphragm 109.

In the previous example, some low frequency energy was removed. Because some low frequency energy was removed, the low frequency response of the electro dynamic transducer 216 would not be as loud as it would have been otherwise. However, because the low frequency response may only be limited for a short time, the perceived low frequency response of the electro dynamic transducer 216 does not change appreciably when compared to the case when the low frequency energy is not removed. The controller 208 dynamically changes in response to the low frequency content of the input audio signal 220 and the excursion estimate 608.

When neither a input signal power limit nor an over-excursion limit is exceeded, the controller 208 instructs the dynamic power limiter 210 to allow the audio signal 224 to pass through the dynamic power limiter 210 with no change. As consequence, the loudness produced by this signal in the electro dynamic transducer 212 remains unchanged as well.

In the case where a over-excursion limit is exceeded and the input signal power limit is not exceeded, the controller 208 instructs the dynamic power limiter 210 to attenuate the low frequency content of audio signal 224. The amount the low frequency content of the audio signal 224 is attenuated by the dynamic power limiter 210 when the over-excursion limit is exceeded and the input signal power limit is not exceeded is different from the amount the audio signal 224 is attenuated when the over-excursion limit is exceeded and the input signal power limit is exceeded. The controller 208 adjusts the amount of low frequency energy removed from the audio signal 224 based on whether both the input signal power limit and the over-excursion limit are exceeded. In addition, the absolute value of the signal power limit and the absolute value of the over-excursion limit determine the amount of low frequency attenuation of the audio signal 224.

In an embodiment of the invention, the controller 208 may be a PID (proportional integral derivative) controller. A PID controller is a generic control loop feedback mechanism widely used in industrial control systems. A PID controller calculates an “error” value as the difference between a measured process variable (e.g. temperature or power) and a desired set point for the variable. The controller attempts to minimize the error by adjusting the process control inputs.

The PID controller calculation involves three separate constant parameters, and is accordingly sometimes called three term control: the proportional, the integral and the derivative values. These values can be interpreted in terms of time: P depends on the present error, I on the accumulation of past errors, and D is a prediction of future errors, based on current rate of change. The weighted sum of these three actions is used to adjust the process via a control element such as the temperature of a voice coil.

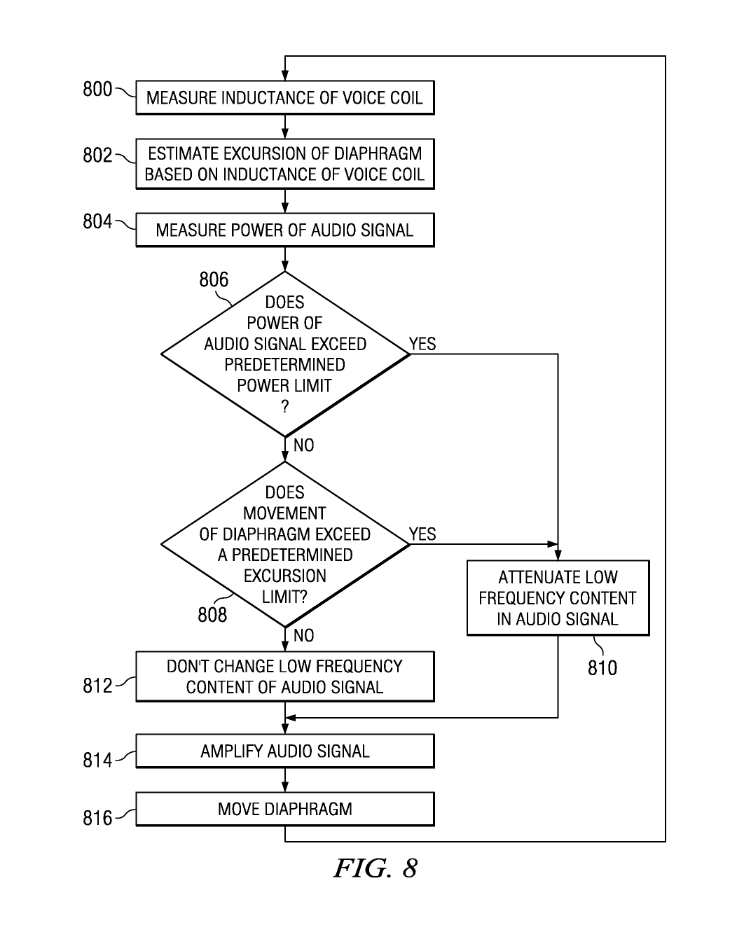

FIG. 8 is a flow diagram of an embodiment of a method of protecting a diaphragm 109 in an electro dynamic transducer 216 from over-excursion. During step 800, the inductance of the voice coil 111 is measured. After measuring the inductance of the voice coil 111, an estimate of the excursion the diaphragm 109 is made during step 802. The estimate of the excursion of the diaphragm 109 can be made using a lookup table or an equation that are based on measured inductance of the voice coil as a function of the excursion of the diaphragm.

During step 804, the power of an audio signal 224 is measured. During step 806, it is determined whether the measured power of the audio signal 224 exceeds a predetermined power limit. When the measured power of the audio signal 224 exceeds the predetermined power limit, the low frequency content of the audio signal 224 is attenuated as shown in step 810. When the measured power of the audio signal 224 does not exceed the predetermined power limit, it is determined during step 808 if the excursion of the diaphragm 109 exceeds a predetermined over-excursion limit. When the excursion of the diaphragm 109 exceeds a predetermined over-excursion limit, the audio signal 224 has low frequency content reduced as shown in step 810.

When the excursion of the diaphragm 109 does not exceed a predetermined excursion limit, the low frequency content of the audio signal 224 is not changed and is passed directly to an amplifier to be amplified as shown in step 812. The amplifier, as shown in step 814, then amplifies the input audio signal. Next the amplifier causes the diaphragm 109 to move. The input audio signal with reduced low frequency content from step 810 is also amplified in step 814 when a power limit or an over-excursion limit is exceeded.

The process shown in FIG. 8 continues to monitor the excursion of the diaphragm 109 and monitor the power of the audio signal 224 in order to prevent over-excursion of the diaphragm 109. The power limit and the over-excursion limit may be set such that perceived loudness of the sound produced by the electro dynamic transducer 212 is nearly the same as when the low frequency content of the audio signal 224 is not attenuated.

In the previous example, the excursion of the diaphragm 109 was estimated by adding a high frequency pilot tone to the audio signal. The reactance of the high frequency pilot tone was used to determine the inductance of the voice coil. For a specific electro dynamic transducer 216, the excursion of a diaphragm 109 can be estimated given the inductance of the voice coil. Other methods may be used to estimate the excursion of the diaphragm 109. For example, the harmonics created in the current domain of the voice coil 111 when the diaphragm 109 is moving may be used to determine the excursion of the diaphragm. The harmonics in the current of the voice coil 111 are dependent on the movement of the diaphragm. As a result, a table or equation can be created for the excursion estimator 602 that would estimate the excursion of the diaphragm 109 based on the harmonics measured in the current of the voice coil 111.

In another example, the excursion of the diaphragm 109 may be estimated by continuously monitor the impedance of the electro dynamic transducer 212. The measured impedance of the electro dynamic transducer 212 can then be compared to an expected impedance curve. Thiele Small (TS) parameters would then be extracted based on the comparison. Changes in the TS parameters would indicate over-excursion. For example, a change in the estimated BL (the product of magnet field strength B in the voice coil gap and the length L of wire in the magnetic field parameter) would indicate over-excursion.

“Thiele/Small” commonly refers to a set of electromechanical parameters that define the specified low frequency performance of a loudspeaker driver. These parameters are published in specification sheets by driver manufacturers so that designers have a guide in selecting off-the-shelf drivers for loudspeaker designs. Using these parameters, a loudspeaker designer may simulate the position, velocity and acceleration of the diaphragm, the input impedance and the sound output of a system comprising a loudspeaker and enclosure. TS parameters include:

S_{d}—Projected area of the driver diaphragm, in square metres.

Mₘₛ—Mass of the diaphragm/coil, including acoustic load, in kilograms. Mass of the diaphragm/coil alone is known as M_{md}

Cₘₛ—Compliance of the driver's suspension, in metres per newton (the reciprocal of its ‘stiffness’).

Rₘₛ—The mechanical resistance of a driver's suspension (i.e., ‘lossiness’) in N·s/m

Lₑ—Voice coil inductance measured in millihenries (mH)

Rₑ—DC resistance of the voice coil, measured in ohms.

Bl—The product of magnet field strength in the voice coil gap and the length of wire in the magnetic field, in tesla-metres (T·m).

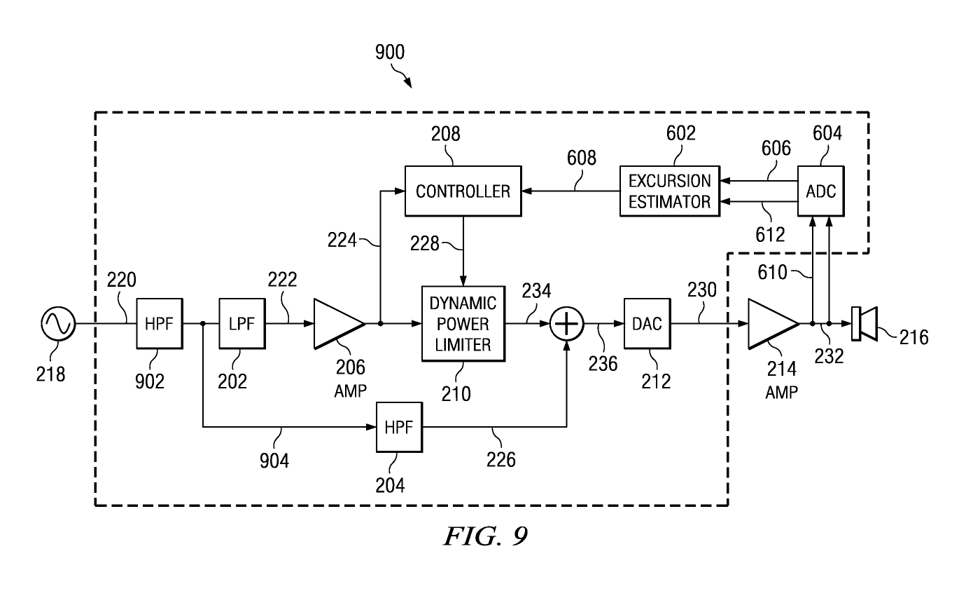

FIG. 9 is a block diagram of a third embodiment of an over-excursion system used to protect an electro dynamic transducer 900. The over-excursion protection system 900 shown in FIG. 9 comprises a high-pass filter 902, a low-pass filter 202, a high-pass filter 204, an amplifier 206 with a gain G, a controller 208, a dynamic power limiter 210, a DAC (digital to analog converter) 212, an ADC (analog to digital converter) 604, and an excursion estimator 602. The over-excursion protection system 900 along with the amplifier 216 may be integrated on a single integrated circuit. In this example, the high-pass filter 902, the low-pass filter 202, the high pass filter 204, the amplifier 206, the excursion estimator 602, the controller 208 and the dynamic power limiter 210 are digital circuits. As consequence, the input audio signal 220 is a digital signal. The protection system 900 shown in FIG. 9 is the same as the protection system 600 shown in FIG. 6 except for the addition of a high-pass filter 902 placed at the input of the protection system 900.

In the embodiment of the invention shown in FIG. 9, the high-pass filter 902 is added to remove low frequency signals that can not be reproduced by an electro dynamic transducer 216. For example, an electro dynamic transducer 216 located in a cell phone may not be able to reproduce frequencies below 300 Hz. Removing the frequencies below 300 Hz in the input audio signal 904, reduces distortion in the electro dynamic transducer 216. In addition, low frequency signals cause more movement in the diaphragm 109 than high frequency signals.

Therefore, removing low frequency signals from the input audio signal helps protect the electro dynamic transducer 216 from over-excursion.

FIG. 5 is an example of a frequency plot of the sum 236 of the output 234 of the dynamic power limiter 210 and the output 226 of the high-pass filter 204 as function of the gain G of the amplifier 206 as shown in FIG. 9. Because the range X of the dynamic power limiter 210 varies between 0 and 1, the output 234 of the dynamic power limiter 210 may vary between 0 and G. When X=1, the frequency response 510 between 300 Hz and 1 KHz is significantly boosted. When X=0.8, the frequency response between 300 Hz and 1 KHz is also boosted. When X=0.6, the frequency response between 300 Hz and 1 KHz is not boosted but is nearly flat to 600 Hz. When X=0, the frequency response of the sum 236 of the output 234 of the dynamic power limiter 210 and the output 226 of the high-pass filter 204 is just the response of the high-pass filter 204.

FIG. 5 illustrates how low frequency signals may be added as a function of the controller 208 and the dynamic power limiter 210. The controller 208 controls the amount of low frequency energy allowed to pass through the dynamic power limiter 210 based on predetermined power limits. The predetermined power limits are determined by measuring the excursion limits of an electro dynamic transducer 212 as a function of the power of the low frequency energy input to an amplifier 214 driving the electro dynamic transducer 216.

The foregoing description has been presented for purposes of illustration and description. It is not intended to be exhaustive or to limit the invention to the precise form disclosed, and other modifications and variations may be possible in light of the above teachings. The embodiments were chosen and described in order to best explain the applicable principles and their practical application to thereby enable others skilled in the art to best utilize various embodiments and various modifications as are suited to the particular use contemplated. It is intended that the appended claims be construed to include other alternative embodiments except insofar as limited by the prior art.

What is claimed is:

1. A method for reducing over-excursion of a diaphragm comprised in an electro dynamic transducer comprising:
measuring the power of an audio signal wherein the audio signal is used to drive an amplifier and wherein an output of the amplifier is electrically connected to the electro dynamic transducer;
attenuating low frequency content in the audio signal when the power of the audio signal exceeds a predetermined power limit;
allowing the low frequency content in the audio signal to be amplified by the amplifier when the predetermined power limit is not exceeded.

2. The method of claim 1 wherein attenuating low frequency content in the audio signal comprises:
filtering an input audio signal such that a second audio signal comprises frequencies above a first cut-off frequency;
filtering the input audio signal such that a third audio signal comprises frequencies below a second cut-off frequency;
increasing the amplitude of the third audio signal by a factor of G wherein the audio signal is equal to the third audio signal multiplied by G;
attenuating the audio signal by a factor of X, wherein X has a value in the range of 0 to 1, wherein the value of X is determined by the predetermined power limit, wherein a fourth audio signal is equal to the audio signal multiplied by X;
adding the fourth audio signal to the second audio signal wherein a fifth audio signal is equal to the fourth audio signal plus the second audio signal;
wherein the fifth audio signal is used to drive the amplifier.

3. The method of claim 2 wherein the first cut-off frequency and second cut-off frequency are approximately equal.

4. A method for reducing over-excursion of a diaphragm comprised in an electro dynamic transducer comprising:
estimating a value for the excursion of the diaphragm;
measuring the power of an audio signal wherein the audio signal is used to drive an amplifier and wherein an output of the amplifier is electrically connected to the electro dynamic transducer;
attenuating low frequency content in the audio signal when the power of the audio signal does not exceed a predetermined power limit and when the excursion of the diaphragm exceeds a predetermined excursion limit;
allowing the low frequency content in the audio signal to be amplified by the amplifier when the predetermined power limit is not exceeded and when the excursion of the diaphragm does not exceed a predetermined excursion limit.

5. The method of claim 4 wherein estimating the value for the excursion of the diaphragm comprises:
applying a high frequency inaudible tone to the electro dynamic transducer;
measuring an imaginary part of the impedance of a voice coil in the electro dynamic transducer;
calculating the inductance of the voice coil in the electro dynamic transducer based on the measured imaginary part of the impedance of the voice coil;
applying a value of the inductance of the voice coil to an excursion estimator wherein the excursion estimator outputs the value of the excursion of the diaphragm.

6. The method of claim 5 wherein the excursion estimator estimates the value of the excursion of the diaphragm using a look-up table, wherein the look-up table is based on measured data that correlates the value of the inductance of voice coil with the excursion of the diaphragm.

7. The method of claim 5 wherein the excursion estimator estimates the value of the excursion of the diaphragm using an equation, wherein the equation is based on measured data that correlates the value of the inductance of voice coil with the excursion of the diaphragm.

8. The method of claim 4 wherein estimating the value for the excursion of the diaphragm comprises:
measuring harmonics in the current in the voice coil of the electro dynamic transducer;
applying the value of the harmonics in the current of the voice coil to an excursion estimator wherein the excursion estimator outputs the value of the excursion of the diaphragm.

9. The method of claim 8 wherein the excursion estimator estimates the value of the excursion of the diaphragm using a look-up table, wherein the look-up table is based on measured data that correlates the value of the harmonics in the current of the voice coil with the excursion of the diaphragm.

10. The method of claim 8 wherein the excursion estimator estimates the value of the excursion of the diaphragm using an equation, wherein the equation is based on measured data that correlates the value of the harmonics in the current of the voice coil with the excursion of the diaphragm.

11. The method of claim 4 wherein estimating the value for the excursion of the diaphragm comprises:
measuring the impedance of the electro dynamic transducer;
comparing the measured impedance of the electro dynamic transducer to an expected impedance of the electro dynamic transducer;
extracting a change in a Thiele Small parameter based on the comparison of the measured and expected impedance of the electro dynamic transducer;
wherein when a change occurs in the Thiele Small parameter, the change indicates over-excursion of the diaphragm.

12. The method of claim 11 wherein the excursion estimator estimates the value of the excursion of the diaphragm using a look-up table, wherein the look-up table is based on measured data that correlates the value of the Thiele Small parameter with the excursion of the diaphragm.

13. The method of claim 4 wherein attenuating low frequency content in the audio signal comprises:
filtering an input audio signal such that a second audio signal comprises frequencies above a first cut-off frequency;
filtering the input audio signal such that a third audio signal comprises frequencies below a second cut-off frequency;
increasing the amplitude of the third audio signal by a factor of G wherein the audio signal is equal to the third audio signal multiplied by G;
attenuating the audio signal by a factor of X, wherein X has a value in the range of 0 to 1, wherein the value of X is determined by the predetermined power limit, wherein a fourth audio signal is equal to the audio signal multiplied by X;
adding the fourth audio signal to the second audio signal wherein a fifth audio signal is equal to the fourth audio signal plus the second audio signal;
wherein the fifth audio signal is used to drive the amplifier.

14. An apparatus comprising:
an electro dynamic transducer, the electro dynamic transducer comprising a voice coil;
a first amplifier; the first amplifier having an input and an output wherein the voice coil is electrically connected to the output of the first amplifier;
a DAC having an output and an input wherein the output of the DAC is electrically connected to the input of the first amplifier;
a dynamic power limiter; the dynamic power limiter having two inputs and an output, the output electrically connected to the input of the DAC;
an ADC having a first and second input and a first and second output wherein an analog voltage across the electro dynamic transducer is presented at the first input of the ADC; wherein an analog current through the electro dynamic transducer is presented at the second input of the ADC; wherein the first output from the ADC is a digital representation of the analog voltage; wherein the second output from the ADC is a digital representation of the analog current;
an excursion estimator, the excursion estimator having a first and second input and an output wherein the first output from the ADC is electrically connected to the first input of the excursion estimator; wherein the second output from the ADC is electrically connected to the second input of the excursion estimator; wherein the output of the excursion estimator outputs a digital value representing the excursion of a diaphragm in the electro dynamic transducer;
a controller, the controller having two inputs and an output wherein a first input is electrically connected to the output of the excursion estimator and the output of the controller is electrically connected to a first input of the dynamic power limiter;
a low-pass filter having an input and an output, wherein the input of the low-pass filter is electrically connected to a digital audio signal;
a second amplifier having an input and an output, wherein the input of the second amplifier is electrically connected to the output of the low-pass filter, wherein the output of the amplifier is connected to a second input of the dynamic limiter and to a second input of the controller;
a high-pass filter having an input and an output, wherein the input of the high-pass filter is connected to the digital audio signal, wherein the output of the high-pass filter is added to the output of the dynamic power limiter;
wherein when the power of a signal from the output of the second amplifier is equal to or greater than a predetermined power value, the dynamic power limiter attenuates low frequency content in the signal from the output of the second amplifier.

15. The apparatus of claim 14 wherein when the output of the excursion estimator is equal to or greater than a predetermined excursion value and the power of the signal from the output of the second amplifier is lower than the predetermined power value, the dynamic power limiter attenuates low frequency content in the signal from the output of the second amplifier.

16. The apparatus of claim 14 wherein when the output of the excursion estimator is less than the predetermined temperature value and the power of the signal from the output of the second amplifier is lower than a predetermined power value, the dynamic power limiter does not change the low frequency content of a audio signal applied to the input of the DAC.

17. The apparatus of claim 14 wherein the apparatus is an electronic device selected from a group consisting of a cellular phone, an electronic tablet, a laptop computer, a desktop computer, a television, a monitor, a portable radio, a portable musical playback system, a PDA and a media player.

18. The apparatus of claim 14 wherein the high-pass filter, the low-filter, the second amplifier, the excursion estimator, the controller and the dynamic power limiter are digital circuits.

19. The apparatus of claim 14 wherein the controller is a PID (proportional integral derivative) controller.

20. The apparatus of claim 14 wherein the high-pass filter, the low-filter, the second amplifier, the excursion estimator, the controller, the first amplifier and the dynamic power limiter are integrated on a single integrated circuit.
